(19) United States
(12) Patent Application Publication
(10) Pub. No.: US 2024/0237230 A1
(43) Pub. Date: Jul. 11, 2024

(54) Component Carrier With Photosensitive Adhesion Promoter and Method of Manufacturing the Same

(71) Applicant: AT&S Austria Technologie & Systemtechnik AG, Leoben (AT)

(72) Inventors: Abderrazzaq Ifis, Georgetown (MY); Claudia Ebner, Edelschrott (AT)

(21) Appl. No.: 18/559,152

(22) PCT Filed: May 7, 2021
(86) PCT No.: PCT/EP2021/062228

§ 371 Date: Nov. 6, 2023

(51) Int. Cl. H05K 3/38; H05K 1/18

(52) U.S. Cl. CPC H05K 3/387; H05K 1/181; H05K 2203/107; H05K 2203/1168

(57) ABSTRACT

A component carrier which comprises a stack comprising at least one electrically conductive layer structure and/or at least one electrically insulating layer structure, and a photosensitive adhesion promoter on or above the stack, wherein only a sub-portion of the photosensitive adhesion promoter is photoactivated, and electrically conductive material selectively on said sub-portion of the photosensitive adhesion promoter.

### CROSS-REFERENCE TO RELATED APPLICATIONS

This application is the U.S. national phase of International Application No. PCT/EP2021/062228 filed 7 May 2021, the disclosure of which is hereby incorporated herein by reference.

### TECHNICAL FIELD

The present disclosure relates to component carriers. Furthermore, the present disclosure relates to methods of manufacturing a component carrier.

### TECHNOLOGICAL BACKGROUND

In the context of growing product functionalities of component carriers equipped with one or more electronic components and increasing miniaturization of such components as well as a rising number of components to be mounted on the component carriers such as printed circuit boards, increasingly more powerful array-like components or packages having several components are being employed, which have a plurality of contacts or connections, with ever smaller spacing between these contacts. Removal of heat generated by such components and the component carrier itself during operation becomes an increasing issue. At the same time, component carriers shall be mechanically robust and electrically reliable so as to be operable even under harsh conditions.

A shortcoming with laminated component carriers is that they may be prone to delamination and/or other phenomena disturbing the performance and/or the reliability of the component carrier.

### SUMMARY

There may be a need to provide a component carrier having a high performance and a high reliability.

According to an exemplary embodiment of a first aspect of the present disclosure, a component carrier is provided, wherein the component carrier comprises a stack comprising at least one electrically conductive layer structure and/or at least one electrically insulating layer structure, and a photosensitive adhesion promoter on or above the stack, wherein only a sub-portion of the photosensitive adhesion promoter is photoactivated, and electrically conductive material selectively on said sub-portion of the photosensitive adhesion promoter.

According to an exemplary embodiment of a second aspect of the present disclosure, a component carrier is provided, wherein the component carrier comprises a stack comprising at least one electrically conductive layer structure and/or at least one electrically insulating layer structure, an adaptive sheet formed on and adhering with the stack, a photosensitive adhesion promoter formed on and adhering with the adaptive sheet, and electrically conductive material formed on and adhering with at least part of the photosensitive adhesion promoter.

According to another exemplary embodiment of the first aspect of the present disclosure, a method of manufacturing a component carrier is provided, wherein the method comprises providing a stack comprising at least one electrically conductive layer structure and/or at least one electrically insulating layer structure, forming a photosensitive adhesion promoter on or above the stack, photoactivating only a sub-portion of the photosensitive adhesion promoter, and selectively forming electrically conductive material only on said sub-portion of the photosensitive adhesion promoter (in particular by a non-selective deposition process).

According to another exemplary embodiment of the second aspect of the present disclosure, a method of manufacturing a component carrier is provided, wherein the method comprises providing a stack comprising at least one electrically conductive layer structure and/or at least one electrically insulating layer structure, forming an adaptive sheet on and adhering with the stack, forming a photosensitive adhesion promoter on and adhering with the adaptive sheet, and forming electrically conductive material on and adhering with at least part of the photosensitive adhesion promoter.

### OVERVIEW OF EMBODIMENTS

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In the context of the present application, the term “stack” may particularly denote an arrangement of multiple planar layer structures which are mounted in parallel on top of one another.

In the context of the present application, the term “layer structure” may particularly denote a continuous layer, a patterned layer or a plurality of non-consecutive islands within a common plane.

In the context of the present application, the term “photosensitive adhesion promoter” may particularly denote a material promoting adhesion of electrically conductive material thereon without a tendency of a loss of a connection or a delamination of electrically conductive material with regard to the adhesion promoter, wherein the adhesion promoting property of the adhesion promoting material can be selectively activated by a photo reaction of the adhesion promoting material with electromagnetic radiation (for instance in the visible range of wavelengths or in the ultraviolet range). Preferably, the photoactivatable adhesion promoter may be configured for changing its surface morphology (for instance by the formation of dendrites) upon photoactivation to thereby become adhesion promoting, in particular for increasing its connection surface by being irradiated with activating electromagnetic radiation (in particular ultraviolet radiation). In particular, the photosensitive adhesion promoter may be present in an adhesion promoting active state or in an adhesion promoting inactive state, wherein the adhesion promoting active state may be activated by supplying heat to the material in the adhesion promoting inactive state. For instance, a photosensitive adhesion promoter as disclosed in WO 2015/165874 A1 may be implemented. An appropriate photosensitive adhesion promoter which may be implemented according to exemplary embodiments of the present disclosure is commercially available from the company Cuptronic Technology. More generally, advantageous properties of a photosensitive adhesion promoter are photosensitive properties upon exposure, a capability to be developed in some areas, and a capability to be fully stripped in some areas. Advantageously, the adhesion promoter may comprise a grafting chemistry capable of altering the resin surface in a way that metals can adhere to a smooth surface. Grafting, in the context of polymer chemistry, describes the addition of polymer chains onto a surface to change the surface properties of a material (for example to promote metal deposition onto it). The provision of such a grafting chemistry may render it dispensable or optional to roughen the surface before an electroless deposition of copper to be applied onto the resin. By using the grafting chemistry, a roughening of the surface before the deposition of electroless copper is not necessary or at least optional. Additionally, the copper traces may have a more defined structure without an undercut.

In the context of the present application, the term “photoactivate” may particularly denote a process of rendering a photosensitive adhesion promoter adhesive for electrically conductive material deposited thereon, in particular by selectively irradiating the photosensitive adhesion promoter with activating electromagnetic radiation of an appropriate wavelength.

In the context of the present application, the term “adaptive sheet” may particularly denote a planar (in particular continuous or patterned) layer made of a material (preferably an electrically insulating material) on which a photosensitive adhesion promoter is formable so that electrically connected material is properly formable, in turn, on the photosensitive adhesion promoter. Not each base material is suitable for forming a functioning photosensitive adhesion promoter thereon. For instance, a significant halogen-content of conventionally used dielectric component carrier materials such as prepreg may be disturbing for a photosensitive adhesion promoter be formed thereon, since halogens may significantly weaken the capability of a photosensitive adhesion promoter to promote adhesion of electrically conductive material formed thereon, in particular by electroless deposition. An adaptive sheet between (for instance halogen-including) stack material and the photosensitive adhesion promoter may have the capability of serving as a proper base for the photosensitive adhesion promoter which does not negatively influence the adhesion promoting capability of the photosensitive adhesion promoter. Descriptively speaking, such an adhesive sheet may spatially separate the photosensitive adhesion promoter with respect to ordinary stack material. For instance, a halogen free resin or prepreg layer may be used as adaptive sheet, for instance a material disclosed in EP 3,219,757. An appropriate adhesive sheet which may be implemented according to exemplary embodiments of the present disclosure is commercially available as “Halogen-free MEGTRON6 R-5375” from the company Panasonic. In particular, any resin sheet can be used as adaptive sheet which does not comprise halogens. Halogens are usually used to achieve certain properties, such as a flame retardancy. However, other components (for example additives) can be used as well to improve the material properties. Further examples of resins are for instance Polyimide, Polyamide, Acrylonitrile-Butadiene-Styrole-Copolymer, Liquid Crystal Polymer, Polyphenylether, Polyetherimide, Polyetheretherketon, and/or Polytetrafluorethylene.

According to an exemplary embodiment of the first aspect of the present disclosure (which may or may not be combined with the second aspect), a component carrier and a corresponding manufacturing concept are provided, in which an electrically conductive material such as copper is applied to a photosensitive adhesion promoter which has been previously photoactivated only on in sub-portion of an exposed surface thereof. As a result, the deposited (in particular electroless deposited) electrically conductive material will remain only and selectively on one or more previously photoactivated sub-portions of the photosensitive adhesion promoter, while the electrically conductive material will not stick to non-activated other sub-portions of the photosensitive adhesion promoter. By such a manufacturing architecture, it may be highly advantageously possible to form a patterned layer of properly adhering electrically conductive material above a stack without the need of photolithographically patterning a mask of photoresist or the like for defining surface portions of the stack selectively covered with electrically conductive material. In contrast to this, it may for instance be sufficient to move an electromagnetic radiation beam along a trajectory corresponding to a surface portion of the photosensitive adhesion promoter for selectively photoactivating only a portion thereof. Since subsequently deposited electrically conductive material will adhere or stick only to the photoactivated portion(s) of the photosensitive adhesion promoter, formation of a patterned metal layer without cumbersome mask technology becomes possible. Descriptively speaking, the described concept allows to define a plateable region on an adhesion promoter by a light mask or beam only without the need of patterning a layer of photoresist or the like. A subsequent electroless deposition may then be limited to the UV-exposed region. This may allow to define electrically conductive portions in a highly accurate way without alignment issues and without etching.

According to an exemplary embodiment of the second aspect of the present disclosure (which may or may not be combined with the first aspect), a component carrier and a corresponding manufacturing concept are provided, in which an adaptive sheet is interposed between a laminated layer stack (for instance formed of copper and prepreg) and a photosensitive adhesion promoter. The latter may form a highly appropriate basis for a deposition of electrically conductive material thereon with high adhesion and with strongly suppressed delamination tendencies. Advantageously, the presence of the adaptive sheet directly below the photosensitive adhesion promoter may remove any incompatibility between ordinary stack material and the photosensitive adhesion promoter. For instance, a substantial halogen content in dielectric material of the stack may disturb the functionality of the photosensitive adhesion promoter. Sandwiching an adaptive sheet between stack and photosensitive adhesion promoter may guarantee simultaneously a proper adhesion of electrically conductive material deposited on the photosensitive adhesion promoter as well as a high freedom of design when configuring the stack material, in particular a dielectric portion thereof. The use of specific (in particular halogen free) dielectric stack material, which would involve a high effort, may become dispensable by an adaptive thin film serving as interaction preventing and function preserving sheet between stack and photosensitive adhesion promoter. Thus, the mentioned adaptive sheet may ensure high intra-layer adhesion and proper reliability of the manufactured component carrier.

Highly advantageously, the described embodiments may provide a semi-additive processing (SAP) type process flow for manufacturing component carriers (such as printed circuit boards, PCBs) without the need of using a mask for creating patterned metal layers. Such a manufacturing architecture may involve low manufacturing effort, may offer a high flexibility, and may ensure a high signal performance. Advantageously, this makes it possible to apply semi-additive processing for all types of stack materials including prepreg. The described concept of forming patterned metal layers may in particular prevent any etching foot, since etching processes are dispensable for this purpose. Consequently, also the effort involved with flash etching as well as dry film formation may be avoided. Nevertheless, a high adhesion of the constituents of the component carrier may be ensured. Descriptively speaking, the (in particular only selectively photoactivated) photosensitive adhesion promoter may function as a seed layer for electroless deposition of electrically conductive material. Advantageously, the photosensitive adhesion promoter may be UV sensitive, i.e. may be selectively photoactivated by ultraviolet radiation. The implementation of a preferably halogen free adaptive sheet between stack and photosensitive adhesion promoter increases the freedom of choice of stack material.

In the following, further exemplary embodiments of the methods and the component carriers will be explained.

In an embodiment, a non-photoactivated other portion of the photosensitive adhesion promoter is not covered by electrically conductive material. By configuring the photosensitive adhesion promoter of a material being adhesion promoting only after photoactivation by irradiation with electromagnetic radiation (such as UV light) or the like, non-heated and therefore non-activated surface portions of the photosensitive adhesion promoter do not show an adhesion promoting function. This makes it possible to non-selectively apply electrically conductive material to the entire surface of the photosensitive adhesion promoter, wherein the electrically conductive material will only adhere and therefore remain attached to the previously selectively activated surface portion, but not to the remaining non-activated surface portion of the photosensitive adhesion promoter.

In an embodiment, the electrically conductive material comprises a first electrically conductive layer and a second electrically conductive layer on the first electrically conductive layer. By forming a second electrically conductive layer on the first electrically conductive layer which is formed, in turn, on activated surface portions of the photosensitive adhesion promoter, it may be possible to increase the thickness of the electrically conductive material up to a freely defined target thickness. For instance, the first electrically conductive layer may have a smaller thickness (which has to be formed on a dielectric underground in form of the photosensitive adhesion promoter) than the second electrically conductive layer (which can be formed with a larger variety of technologies, since it can be formed on an electrically conductive underground). As known by those skilled in the art of PCB technology, a borderline between subsequently formed electrically conductive layers can be clearly seen in a cross-sectional image of the component carrier. It is also possible to form an electrically conductive material of more than two stacked layers.

In an embodiment, at least part of the first electrically conductive layer is formed by electroless deposition. Since the photosensitive adhesion promoter is in many cases (however not always) a dielectric material, electroless deposition or sputtering are appropriate methods of forming the first electrically conductive layer thereon. In particular, the first electrically conductive layer may be formed by a pure electroless deposition method. More generally, the first electrically conductive layer may be formed by a purely chemical process or by sputtering.

In an embodiment, the second electrically conductive layer is formed by a galvanic process. During galvanic deposition of the second electrically conductive layer on the first electrically conductive layer, an electric current may be applied the previously formed first electrically conductive layer to trigger galvanic deposition. Galvanic deposition is a simple process of thickening a previously formed chemically or physically applied metal layer in form of the first electrically conductive layer.

In an embodiment, the method comprises providing the photosensitive adhesion promoter with a grafting chemistry configured to alter a surface of resin for promoting a subsequent formation of electrically conductive material when photoactivated. More specifically, it may be possible to use a grafting chemistry to alter the surface of resins for a subsequent metal deposition.

In an embodiment, the electrically conductive material has a rectangular shape in a cross-sectional view. By avoiding slanted sidewalls as well as sidewalls with structural artefacts deviating from a vertical wall geometry, a homogeneous and smooth sidewall may be obtained. In view of the skin effect, signals propagating at high frequency concentrate on a thin skin of an electrically conductive trace. By configuring the electrically conductive material with a precisely rectangular shape thanks to the above-described manufacturing process, its use as metallic trace in particular for high-frequency signals is of utmost advantage.

In an embodiment, the electrically conductive material is free of an undercut. Undercuts in a foot region of a metallic trace are a typical artifact created by an etching process which can be avoided by forming the electrically conductive material by electroless deposition on a selectively photoactivated adhesion promoter rather than using a dry film to be patterned by etching. By avoiding etching feet or undercuts by forming a straight sidewall of the electrically conductive material, in particular the high-frequency properties of the component carrier may be significantly improved.

In an embodiment, the adaptive sheet is made of a non-halogenated material, in particular of a non-halogenated resin or a non-halogenated prepreg. The halogens are a group of elements in the periodic table comprising in particular fluorine (F), chlorine (Cl), and bromine (Br). In the IUPAC nomenclature, this group may be denoted as group 17. In resin, chlorine and bromine may be the most relevant halogens. It has turned out that the adhesion promoting capability of photosensitive adhesion promoters, in particular of the type which change their surface morphology by photoactivation, may be functionally worsened in the presence of halogen-including materials. Consequently, an adaptive sheet made of a material which is substantially free of halogen may be of utmost advantage for the overall properties of the component carrier. However, a person skilled in the art will understand that each material, even a non-halogenated material, may comprise small amounts or residues of halogen. According to the standard IEC 61249-2-21 of the International Electrotechnical Commission (IEC), a non-halogenated or halogen-free material for a printed circuit board which may be implemented according to exemplary embodiments of the present disclosure may have not more than 900 ppm maximum Cl, not more than 900 ppm maximum Br, and not more than 1500 ppm maximum total Cl and Br.

In an embodiment, the adaptive sheet is free of filler particles (in particular filler spheres). Filler particles may be included in a resin system for adding a functionality, in particular for enhancing thermal conductivity. However, filler particles have been identified as an origin for weakening adhesion of an adaptive sheet within a laminated layer sequence. Omitting filler particles may thereby improve the properties of the adaptive sheet.

By taking the measures of one or more of the three preceding paragraphs and/or other appropriate measures in terms of selection of material(s), dimension and/or geometry of the adaptive sheet, the adaptive sheet may be configured for functionally decoupling the photosensitive adhesion promoter from the stack (in particular from a closest one of the at least one electrically insulating layer structure of the stack), wherein the photosensitive adhesion promoter would be partially or entirely functionally inactivated by the stack (in particular by the closest one of the at least one electrically insulating layer structure), without the adaptive sheet. In particular when being in direct physical contact with an electrically insulating layer structure comprising halogenated material (such as standard halogenated prepreg), this may deteriorate or even completely destroy the adhesion promoting property of the adhesion promoter. Such an undesired phenomenon can be avoided by the adaptive sheet, which needs a configuration for avoiding reduction or loss of adhesive properties of the adhesion promoter.

In an embodiment, the adaptive sheet has a thickness of not more than 5 μm, in particular in a range from 2 μm to 4 μm. By such a thin adaptive sheet or film, it can be ensured that the adaptive sheet does not contribute significantly to the thickness of the component carrier and will thus not significantly influence the properties of the component carrier as a whole, apart from helping the adhesion promoter to properly carry out its adhesion promoting function.

In an embodiment, the at least one electrically insulating layer structure of the stack comprises a halogenated material, in particular a halogenated resin. According to the standard IEC 61249-2-21 of the International Electrotechnical Commission (IEC), a non-halogenated or halogen-free material for a printed circuit board may have not more than 900 ppm maximum Cl, not more than 900 ppm maximum Br, and not more than 1500 ppm maximum total Cl and Br. A halogenated resin may have more than 900 ppm, in particular more than 1800 ppm, Cl, more than 900 ppm, in particular more than 1800 ppm, Br, and more than 1500 ppm, in particular more than 3000 ppm, total Cl and Br. Dielectric stack material which does not have to be de-halogenated, may be significantly cheaper than non-halogenated dielectric stack material. Thanks to the above-described adaptive sheet and its properties, it may be possible to implement substantially any dielectric resin material in the stack without negatively influencing the functionality of the photosensitive adhesion promoter.

If for instance no adaptive sheet is present between the stack and the photosensitive adhesion promoter, it may be preferred that the at least one electrically insulating layer structure of the stack comprises a non-halogenated material, in particular a non-halogenated resin. Although this may involve additional effort in terms of the provision of the electrically insulating layer structure(s), this may guarantee a proper functionality of the photosensitive adhesion promoter if no adaptive sheet is present.

In an embodiment, the electrically conductive material defines a wiring structure having a line/space ratio of not more than 5 μm/5 μm (i.e. a line of not more than 5 μm and a space of not more than 5 μm), in particular of not more than 2 μm/2 μm (i.e. a line of not more than 2 μm and a space of not more than 2 μm). In PCB technology, line/space ratio may denote the ratio between a horizontal width of an electrically conductive line (which may be constituted by an electrically conductive material manufactured as described herein) and a distance being adjacent sidewalls of two adjacent electrically conductive lines (which may each be constituted by an electrically conductive material manufactured as described herein). In view of the provision of the photosensitive adhesion promoter which can be spatially selectively photoactivated by an electromagnetic radiation beam, extremely tiny electrically conductive structures with highly precise position and extension may be created. This allows to obtain the mentioned very low line/space ratios. In particular, defining the photoactivated portions of the photosensitive adhesion promoter by a laser beam (for instance in the UV range) may ensure a very high degree of spatial accuracy in terms of line width and distance between lines.

In an embodiment, the photosensitive adhesion promoter comprises polymer dendrites in a photoactivated sub-portion thereof. More specifically, the photoactivated sub-portion of the photosensitive adhesion promoter comprises (in particular polymer) dendrites. Furthermore, a non-photoactivated portion of the photosensitive adhesion promoter does not comprise (in particular polymer) dendrites, but comprises a grafting chemistry configured for forming (in particular polymer) dendrites in its photoactivated state. Such dendrites may be polymers formed based on monomers of the photosensitive adhesion promoter and may be created by a heat impact. The chemistry of a corresponding formulation may be a grafting chemistry. Grafting means that monomers chemically bond or physically adhere to the resin sheet. After UV exposure, polymers start to grow from these surfaces, which may be in particular polymer dendrites. Thus, the dendrites may be polymer dendrites. Dendrite growth may be the growth of (in particular dielectric) filaments forming part of the photoactivated adhesion promoter. Descriptively speaking, such dendrites may increase the surface area of the adhesion promoter which improves the adhesion between the adhesion promoter and electrically conductive material.

In an embodiment, the electrically conductive material on the photosensitive adhesion promoter forms one of the group consisting of at least one pad, at least one wiring, at least one pillar, and at least one seed layer in a hole (for instance a via or a plated through hole) in the stack. Thus, a grafting chemistry can be also used for vias and plated through holes. Also, the formation of electrically conductive traces is possible in exemplary embodiments. Hence, any desired type of metallic structures can be formed by exemplary embodiments of the present disclosure.

In an embodiment, the photosensitive adhesion promoter has a higher roughness Rz in a photoactivated sub-portion compared to a remaining other non-photoactivated sub-portion thereof. In the context of the present application, the term “roughness Rz” may particularly denote a measure for the roughness which can be determined when a reference length is sampled from a roughness curve in a direction of a mean line, and may denote the distance between the top profile peak line and the bottom profile valley line on this sampled portion as measured in the longitudinal direction of the roughness curve (for instance, Rz may be determined by averaging over five individual measuring paths). For example, the measurement or determination of roughness Rz may be carried out according to DIN EN ISO 4287:1984. By selectively increasing the roughness Rz by photoactivation of only the part of the adhesion promoter, the spatial selectivity of the deposition of electrically conductive material only on photoactivated material of the adhesion promoter can be further increased.

In an embodiment, the photosensitive adhesion promoter and/or the adaptive sheet on the one hand and the at least one electrically insulating layer structure on the other hand comprise different resin materials. This increases the freedom of design for a component carrier designer in terms of material selection. Both resin systems may be selected independently in accordance with their desired functions.

In an embodiment, a thickness of the at least one electrically insulating layer structure is larger than, in particular at least 5 times of, a thickness of the adaptive sheet. Hence, the concept of adding an adaptive sheet is compatible with any desired component carrier design and in particular independent of the thickness of the electrically insulating layer structures of the stack. Consequently, apart from supporting the function of the adhesion promoter, the adaptive sheet does not influence the properties of the component carrier.

In an embodiment, a sub-portion of the photosensitive adhesion promoter has adhesion promoting properties whereas a remaining other sub-portion of the photosensitive adhesion promoter has non-adhesion promoting properties. The portions may be defined by a spatially varying heat impact. This allows a selective deposition of the electrically conductive material, and the electrically conductive material will remain attached only on the photoactivated portion of the adhesion promoter.

In an embodiment, the photosensitive adhesion promoter is a photosensitive adhesion promoter layer arranged parallel to the layer structures of the stack. Thus, the adhesion promoter may be a continuous or patterned layer with homogeneous thickness and homogeneous material properties prior to photoactivation. For instance, such an adhesion promoter may be laminated, printed or dispensed on the entire surface of the stack.

In an embodiment, the method comprises activating the photosensitive adhesion promoter by supplying heat, in particular in form of electromagnetic radiation, more particularly in form of ultraviolet radiation. In particular, the method may comprise selectively treating a sub-portion of the photosensitive adhesion promoter with heat, in particular by a beam of electromagnetic ultraviolet radiation, to thereby define a sub-portion of the photosensitive adhesion promoter layer on which electrically conductive material is selectively depositable. Preferably, spatially selective activation of a sub-portion of the adhesion promoter may be carried out with a laser beam which can be created in a spatially strongly confined way. Thus, a laser beam, and in particular an ultraviolet laser beam, may be a highly appropriate choice for the definition of the region on which the electrically conductive material is to be formed.

In an embodiment, the method comprises photoactivating only the sub-portion of the photosensitive adhesion promoter by laser direct imaging (LDI). Laser direct imaging may expose the photosensitive adhesion promoter directly with a highly focused laser beam so that the laser beam will create the image defining the selectively photoactivated sub-portion. Hence, by a spatially selective photoactivation of the adhesion promoter by LDI, a high spatial accuracy may be obtained without alignment issues while simultaneously avoiding a cumbersome dry film processing.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular coated with supra-conductive material or conductive polymers, such as graphene or poly(3,4-ethylenedioxythiophene) (PEDOT), respectively.

At least one component may be embedded in the component carrier and/or may be surface mounted on the component carrier. Such a component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be a IC substrate, an interposer or a further component carrier, for example in a board-in-board configuration. The component may be surface mounted on the component carrier and/or may be embedded in an interior thereof. Moreover, also other components, in particular those which generate and emit electromagnetic radiation and/or are sensitive with regard to electromagnetic radiation propagating from an environment, may be used as component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

The aspects defined above and further aspects of the present disclosure are apparent from the examples of embodiment to be described hereinafter and are explained with reference to these examples of embodiment.

### BRIEF DESCRIPTION OF THE DRAWINGS

FIG. 1, FIG. 2, and FIG. 3 illustrate cross-sectional views of structures obtained during carrying out a method of manufacturing a component carrier, shown in FIG. 3, according to an exemplary embodiment of the present disclosure.

FIG. 4 illustrates cross-sectional views of a component carrier according to an exemplary embodiment of the present disclosure.

### DETAILED DESCRIPTION OF EXEMPLARY EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the present disclosure have been developed.

According to an exemplary embodiment of the present disclosure, a manufacturing method for component carriers is provided in which a photosensitive adhesion promoter can be selectively photoactivated by a patterned electromagnetic radiation beam or by an electromagnetic radiation beam moving along a trajectory corresponding to a target surface portion of the photosensitive adhesion promoter. Thereafter, electroless deposition of a patterned metallic layer corresponding to the electrically photoactivated pattern of the photosensitive adhesion promoter can be carried out without the need of photolithographically patterning a photoresist layer. In order to avoid any undesired impact from halogen content and/or other disturbing influences of stack material of the component carrier on the functionality of the photosensitive adhesion promoter, an adaptive sheet may be interposed between stack and photosensitive adhesion promoter. The material of the adaptive sheet may be specifically selected to be compatible with and to protect the photosensitive adhesion promoter (for instance may be halogen free) and to be properly attachable to the stack.

In particular, exemplary embodiments may implement an adhesion promoter which ensures a high adhesion between the base material of the stack and deposited metal. Descriptively speaking, an adhesion promoter may be used which forms polymer dendrites when being photoactivated. Such dendrites may increase the connection area with the electrically conductive material thereon and may thereby promote adhesion. Advantageously, a photosensitive adhesion promoter can be exposed with laser direct imaging (LDI), so that even tiny portions of a photosensitive adhesion promoter layer may be selectively activated by a very narrow laser beam. Consequently, electrically conductive traces can be created with high accuracy and very low line width. Exemplary embodiments of the present disclosure may make it possible to print a design with an electromagnetic radiation beam on a photosensitive adhesion promoter which translates into a corresponding electrically conductive trace pattern by electroless deposition. When used in terms of semi additive processing of the component carrier, a conventional need for a dry film may become dispensable.

Highly advantageously, an adaptive sheet may be implemented in the component carrier for high reliability. It is a challenge for plating and adhesion promoting applications that such solutions do not fit to the entire wide range of base materials that exist in component carrier technology. In order to overcome such conventional shortcomings, an exemplary embodiment of the present disclosure provides an adaptive sheet as an intermediate layer between base materials of a stack and the adhesion promoter. Hence, it may be possible to interpose an adaptive sheet which is designed with properties to adhere to both the base material and the adhesion promoter. For example, such an adaptive sheet may be pressed together with the base material. As the adaptive sheet is to be pressed to the stack material, the adaptive sheet may have flowing properties as well as adhesion properties to allow it to mix and adhere with the base material. The sheet can be for instance made from the same resin system as prepreg of the stack while constituents should be removed that may compromise the adhesion with the photosensitive adhesion promoter. For instance, adhesion promoters usually show only a poor adherence with halogenated materials. Preferably, the adaptive sheet should therefore be halogen free.

In some other case, when using copper foils, the adhesion to the base material may be compromised by certain fillers. In this case, those fillers should be reduced or fully removed from the adaptive sheet. In particular, the adaptive sheet may be free of filler particles.

Furthermore, the adaptive sheet may include additives that improve the adhesion.

Advantageously, for more safety it may be preferred to process in two press stages: In a first stage, it may be possible to press the base material alone or to implement a foil that can create a certain profile. A second press stage of the adaptive sheet may be carried out after removing any used foil in the first press (for instance implementing a release or etching process).

Advantageously, the adaptive sheet should be neutral as much as possible in terms of electrical and mechanical properties. In this case, the adaptive sheet should be thin and preferable from the same resin system as the base material. Moreover, it is preferred that the material of the adaptive sheet does not contain any constituent which may be the origin of low adhesion. Further preferably, the resin forming a matrix of the adaptive sheet may contain adhesion promoters. Furthermore, the adaptive sheet may be free of glass fibers. The adaptive sheet may be covered with a protection foil prior to use. Such a protection foil can remain in the build-up of the component carrier or may be removed before completing manufacture of the component carrier.

Descriptively speaking, the adaptive sheet may be used for adhesion purposes and/or any other purpose of preventing negative interactions between the base material (i.e. the stack) and directly adjacent material (i.e. the photosensitive adhesion promoter).

Advantageously, the implementation of an adaptive sheet may provide a standardized and universal solution to overcome poor compatibility between stack material and material of a photosensitive adhesion promoter. Moreover, an adaptive sheet may ensure a high adhesion and reliability as well as a high flexibility in terms of build-up. Modularization requires flexibility and universal solutions. Embodiments of the present disclosure may provide such a flexibility to handle different materials and build ups.

Considering the trend of continuous miniaturization of component carriers, a direct plating solution instead of using copper foils may be a preferred option. This becomes possible according to exemplary embodiments of the present disclosure. Hence, exemplary embodiments provide component carriers configured as highly reliable embedded packages. Also, with the described techniques, it may be possible to embed all component sizes and shapes in the same core.

According to an exemplary embodiment of the present disclosure, an electrically conductive material may be formed on a light-patterned photosensitive adhesion promoter by direct plating (i.e. without copper foil in between) on prepreg covered with low adhesion material. In this case, a photosensitive adhesion promoter may be highly advantageous since it may ensure a very high adhesion to copper. For instance, the adhesion comes from grown polymer dendrites on the base material. However, an adhesion promoter will not work properly on a base which comprises halogen. Descriptively speaking, the adhesion promoter may work improperly on such a base, as the dendrites cannot grow with halogens around. By providing a halogen free adaptive sheet that is pressed on top of a conventional layer stack of a component carrier, the adhesion promoter on such an adaptive sheet may work properly without undesired impact on the electrical performance of the build-up.

Hence, it may be possible to introduce a bridging material between stack and adhesion promoter to decrease the failure risks, adhesion issues, and delamination in the border region between base material and copper layer. By using such an adaptive sheet, it may be possible to widen the border region and to create a smooth transition region by partially assimilating material properties of the adaptive sheet to both the base material surface and the copper layer surface.

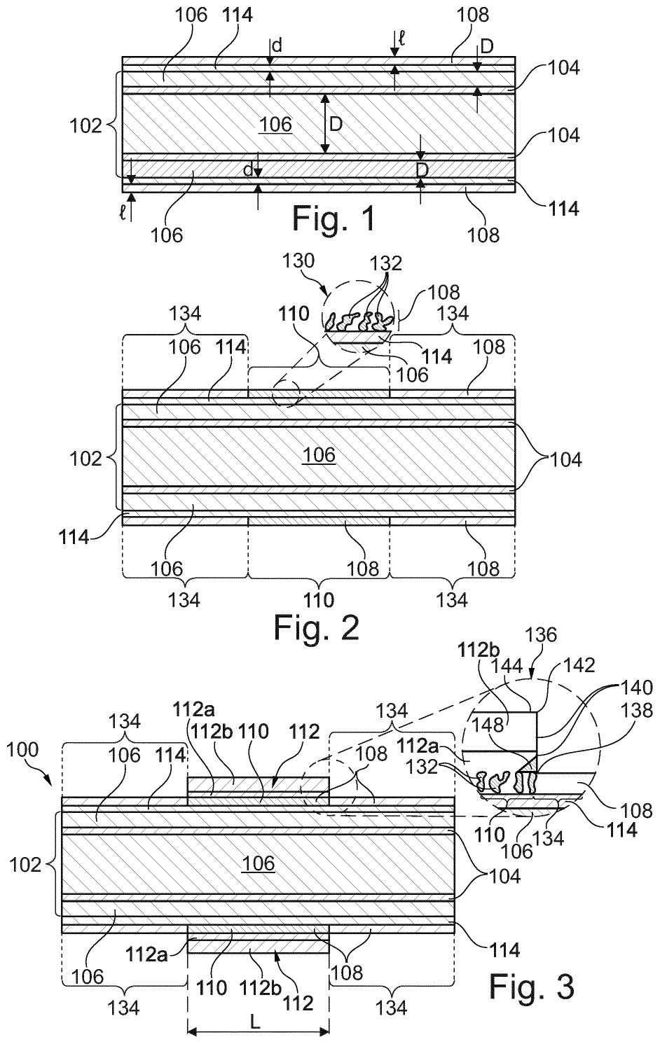

FIG. 1, FIG. 2, and FIG. 3 illustrate cross-sectional views of structures obtained during carrying out a method of manufacturing a component carrier 100, shown in FIG. 3, according to an exemplary embodiment of the present disclosure.

Descriptively speaking, the corresponding manufacturing architecture may be denoted as a semi additive processing (SAP) process flow enabling to produce a patterned electrically conductive material 112 on a laminated layer stack 102 by selectively irradiating a corresponding sub portion of a photosensitive adhesion promoter 108 on the stack 102 with electromagnetic radiation (preferably in the UV wavelength range). This may make it possible to spatially define a plateable portion on the stack 102 without the need to deposit or attach and subsequently pattern by etching a photoresist or dry film before executing a metal deposition. Moreover, interposing a thin adaptive sheet 114 between an ordinary printed circuit board (PCB) layer sequence on the one hand and the photosensitive adhesion promoter 108 on the other hand may allow to avoid any incompatibility or undesired functional interaction between the freely designable layer sequence of the stack 102 and the photosensitive adhesion promoter 108. In particular, the material properties of such an adaptive sheet 114 may be selected so as to ensure a proper adhesion with both the layer stack 102 and the photosensitive adhesion promoter 108 while simultaneously avoiding any undesired impact on the functionality of the photosensitive adhesion promoter 108. Details of such a highly advantageous manufacturing concept and of a construction of the correspondingly manufactured component carrier 100 will be explained in the following:

Referring to FIG. 1, a laminated layer stack 102 is shown which comprises one or a plurality of electrically conductive layer structures 104 (two in the shown embodiment) and one or a plurality of electrically insulating layer structures 106 (three in the shown embodiment). Lamination may particularly denote the connection of the layer structures 104, 106 by the application of pressure and/or heat. For example, the electrically conductive layer structure(s) 104 may comprise patterned or continuous copper foils (as shown) and vertical through-connections (not shown), for example copper filled laser vias which may be created by plating. The electrically insulating layer structure(s) 106 may comprise a respective resin (such as a respective epoxy resin), preferably comprising reinforcing particles therein (for instance glass fibers or glass spheres). For instance, the electrically insulating layer structures 106 may be made of prepreg or FR4. In the shown embodiment, a central electrically insulating structure 106 is covered on both opposing main surfaces thereof with a respective electrically conductive layer structure 104. For instance, the mentioned portion of stack 102 shown in FIG. 1 may be a fully cured core. Each of the opposing exposed surface portions of the electrically conductive layer structures 104 may be covered with a further electrically insulating layer structure 106, for instance a prepreg sheet. However, in other embodiments, stack 102 may be constructed otherwise, for instance may include one or more additional horizontal and/or vertical electrically conductive and/or electrically insulating layer structures.

For instance, a thickness, D, of a respective one of the electrically insulating layer structures 106 of the laminated layer stack 102 may be in a range from 10 μm to 500 μm, in particular in a range from 30 μm to 200 μm. Different electrically insulating layer structures 106 may have different thicknesses, D. According to the described embodiment of the present disclosure, there is substantially no limitation concerning the materials used for constructing the stack 102. It is in particular possible to use relatively cheap prepreg materials for the electrically insulating layer structure(s) 106, and no care has to be taken that the electrically insulating layer structures 106 are for instance halogen-free. Halogen-free prepreg is expensive, so that the freedom of a designer to use any desired resin-system for the electrically insulating layer structures 106—thanks to the provisions described below in further detail—may be of utmost advantage.

After having provided laminated layer stack 102 with any desired properties and made of any desired material, a respective adaptive sheet 114 may be attached on each of the two opposing main surfaces of the layer stack 102 so as to adhere with the stack 102 and cover the stack 102 on both sides. Each adaptive sheet 114 is in direct physical contact with a respective exterior one of the electrically insulating layer structures 106 of the stack 102. It goes without saying that it is also possible to provide an adaptive sheet 114 only on one main surface of stack 102.

Preferably, the adaptive sheet 114 is configured as a thin film of a homogeneous material and thickness. Advantageously, thickness, d, of each of the adaptive sheets 114 may be for instance in a range from 2 μm to 5 μm. Hence, the adaptive sheet 114 does not contribute significantly to the overall thickness of the component carrier 100 to be manufactured. The adaptive sheets 114 have the functions (i) to enhance adhesion between stack 102 and a photosensitive adhesion promoter 108 which is to be formed subsequently on the respective adaptive sheet 114 as described below in further detail, and (ii) to spatially and functionally decouple the stack 102 from the photosensitive adhesion promoter 108. In order to accomplish this, each adaptive sheet 114 is made of a non-halogenated resin, i.e. a resin such as an epoxy resin, which does not comprise a noteworthy amount of halogen material. It has been surprisingly found that a substantial halogen content in a prepreg which may be used for instance as electrically insulating layer structure 106 in direct physical contact with a photosensitive adhesion promoter 108 may significantly disturb the function of the adhesion promoter 108 formed directly thereon. Therefore, bringing the photosensitive adhesion promoter 108 to be formed subsequently in direct physical contact with halogen-free adaptive sheet 114 may significantly improve the adhesion promoting function of the photosensitive adhesion promoter 108. Moreover, it has turned out to be highly advantageous if the adaptive sheet 114 is free of filler particles. It has been found that filler particles (which may be used conventionally for improving thermal conductivity, etc.) may have a negative impact on an adhesion with a corresponding adhesion promoting layer 108. Since the adaptive sheets 114 are anyway formed as extremely thin films, omitting filler particles therein has substantially no impact on the overall properties of the component carrier 100, but may significantly improve the adhesion properties around adaptive sheets 114.

After having attached the adaptive sheets 114 to the stack 102, a thin film of photosensitive adhesion promoter 108 may be formed on each adaptive sheet 114 so as to properly adhere thereon. Adhesion promoter application may be carried out for example by dispensing, printing, lamination, or deposition. An applied grafting chemistry (which may be a liquid) alters the surface chemistry of the adaptive sheet to allow for electroless copper deposition. The grafting chemistry can be applied by spraying, dipping, rolling, a conveyor, etc. The applied photosensitive adhesion promoter 108 may have a thickness, l, which may be even smaller than the thickness, d, of the adaptive sheet 114. For example, thickness, l, may be in a range from 100 nm to 2 μm, in particular in a range from 200 nm to 1 μm. For instance, the photosensitive adhesion promoter 108 may be of the type which is, as such, not adhesion promoting, but gains its adhesion promoting function by being photo-activated, i.e. by being irradiated with electromagnetic radiation of an appropriate wavelength.

Referring to FIG. 2, only a sub-portion 110 of the photosensitive adhesion promoter 108 may then be selectively photoactivated, i.e. may be converted from a non-activated non-adhesion promoting state to an activated adhesion promoting state. Although not illustrated in FIG. 2, selective photoactivation only of sub-portion 110, but not of the remaining portions 134 of photosensitive adhesion promoter 108, may be accomplished by selectively supplying heat to said sub-portion 110. Heat activation may be triggered by irradiating only sub-portion 110 with electromagnetic radiation in an appropriate wavelength range, preferably in form of ultraviolet (UV) radiation. For example, the spatial selectivity of the activation of only sub-portion 110 with ultraviolet radiation may be accomplished by moving an electromagnetic radiation source (not shown) emitting a beam of photoactivating electromagnetic radiation along a trajectory adjusted for selectively irradiating only the sub-portion 110 to be activated with the activating electromagnetic radiation. Preferably, photoactivating of only the sub-portion 110 of the photosensitive adhesion promoter 108 may be accomplished by laser direct imaging (LDI). LDI may expose exclusively the sub-portion 110 of the photosensitive adhesion promoter 108 directly and with a highly focused laser beam which will create the image defining the selectively photoactivated sub-portion 110.

Alternatively, it is also possible to selectively define the sub-portion 110 to be photoactivated by directing light through a UV-absorbing mask (not shown) between an electromagnetic radiation source and the photosensitive adhesion promoter 108. Hence, a broad beam of electromagnetic radiation may be selectively absorbed by the mask having one or more openings corresponding to the sub-portion 110.

Hence, it may be possible to selectively treat only the photoactivated sub-portion 110 of the photosensitive adhesion promoter 108 with the beam of electromagnetic ultraviolet radiation to thereby define the sub-portion 110 of the respective layer of photosensitive adhesion promoter 108 on which electrically conductive material 112 is later selectively depositable. Non-irradiated other portions 134 of the photosensitive adhesion promoter 108, which may be denoted as non-photoactivated sub-portions 134, remain inactive and will later be incapable to form a basis for deposition of the electrically conductive material 112, since the latter will not adhere on non-activated surface portions of the photosensitive adhesion promoter 108. Consequently, the described UV exposure selectively only of sub-portion 110 may define any desired structure or pattern according to which electrically conductive material 112 can later be deposited. The non-photoactivated sub-portions 134 should be preferably removed (for instance by etching, washing or rinsing) before completing manufacture of a component carrier 100, or they may remain part of the readily manufactured component carrier 100.

Descriptively speaking, the spatially selective heat-activation only of sub-portion 110 of the photosensitive adhesion promoter 108 may allow the formation of patterned electrically conductive material 112 without the need of depositing and patterning a dry film or photoresist layer for defining surface regions of the stack 102 to be covered selectively with electrically conductive material 112. The heat-based selective surface activation of only the sub-portion 110 of the photosensitive adhesion promoter 108 according to an exemplary embodiment of the present disclosure renders the manufacturing process significantly simpler.

As can be taken from a detail 130 of FIG. 2, selective photoactivation of sub-portion 110 of the photosensitive adhesion promoter 108 may result in the formation of polymer dendrites 132. Descriptively speaking, dendrites 132 may locally increase the surface area of photosensitive adhesion promoter 108 and may thereby improve the adhesion properties thereof.

Referring to FIG. 3, it may then be possible to selectively form electrically conductive material 112 only on said selectively photoactivated sub-portion 110 of the photosensitive adhesion promoter 108. Hence, copper is built only on the activated area(s) of the photosensitive adhesion promoter 108. As shown, the formed electrically conductive material 112 is composed of a first electrically conductive layer 112a and a separate second electrically conductive layer 112b on the first electrically conductive layer 112a. The photoactivated sub-portion 110 of the adhesion promoter 108 is properly conditioned, by the photoactivation using heat/UV light, to function as a seed layer and thereby to serve as an adhesive basis for the first electrically conductive layer 112a.

The first electrically conductive layer 112a is deposited selectively on the photoactivated sub-portion 110 of the adhesion promoter 108 by electroless deposition or by sputtering. In contrast to this, electroless deposition and sputtering may be incapable of forming electrically conductive material which remains attached on non-photoactivated surface portions 134 of the photosensitive adhesion promoter 108, since electrically conductive material will not attach and remain there. In view of its manufacture by electroless plating, electrically conductive layer 112a may be denoted as electroless plating layer. Said electroless plating layer or electrically conductive layer 112a may denote a metallic structure formed by chemical processes that create metal coatings on underlying material (which may also be non-metallic, as the photosensitive adhesion promoter 108) without electricity, in particular by an autocatalytic chemical reduction of metal cations in a liquid bath. Electroless plating is contrasted with electroplating processes, such as galvanization, where the reduction and deposition of a metal is achieved by an externally generated electric current. Electroless plating may also be denoted as chemical plating or autocatalytic plating. For instance, chemical copper, nickel and/or palladium may be applied by electroless plating as the first electrically conductive layer 112a.

After formation of the first electrically conductive layer 112a by electroless deposition or sputtering, it may be possible to form a second electrically conductive layer 112b on top of the first electrically conductive layer 112a for thickening the electrically conductive material 112 up to a target thickness. Although thickening may be highly advantageous for certain applications, formation of the second electrically conductive layer 112b is optional. The second electrically conductive layer 112b, if present, may be formed on the first electrically conductive layer 112a by an electroplating process, in particular by galvanic plating. Hence, if desired or required, the electroless deposited metallic material of the first electrically conductive layer 112a may be further thickened by a subsequent optional galvanic metal deposition process by which additional metallic material may be galvanically deposited as the second electrically conductive layer 112b on exposed surfaces of the first electrically conductive layer 112a.

It may be preferred for certain PCB applications that both the first electrically conductive layer 112a and the second electrically conductive layer 112b are made of copper. However, other materials such as nickel or gold may be possible as well for the first electrically conductive layer 112a and/or the second electrically conductive layer 112b. By galvanic plating or the like, the first electrically conductive layer 112a (for instance made of chemical copper, nickel and/or palladium) may be covered with the second electrically conductive layer 112b (for instance made of galvanic copper, silver and/or gold). The latter may be made of different materials such as chemical silver, chemical tin or a nickel-gold surface. Hence, the first electrically conductive layer 112a and the second electrically conductive layer 112b may be made of the same material or may be made of different materials.

As shown in a detail 136 of FIG. 3, the described manufacturing process can be carried out in such a way that the obtained electrically conductive material 112 shows a precise rectangular shape. Advantageously, this can be achieved by the selective photoactivation of only sub-portion 110 of photosensitive adhesion promoter 108 and therefore without a cumbersome etching process. Again referring to detail 136, said rectangular shape is characterized by vertical sidewall 140 of the electrically conductive material 112, wherein a right angle is formed at a step 138 between the non-photoactivated sub-portion 134 and the vertical sidewall 140. In contrast to conventional concepts of manufacturing electrically conductive material 112 involving etching, undesired undercuts are not present at step 138.

For comparison purposes, an undesired undercut or etching foot which may occur in a conventional etching-based patterning process is indicated with reference sign 148 in detail 136.

Additionally, a right angle is formed at a step 142 between a horizontal surface of a top wall of the electrically conductive material 112 and the vertical sidewall 140 of the electrically conductive material 112. Electrically conductive material 112 formed as a precise rectangle in a cross-sectional view ensures a highly advantageous signal transport along the electrically conductive material 112 when operated as electrically conductive trace of a component carrier 100 such as a printed circuit board (PCB). Furthermore, such a signal transport along a rectangular trace involves low loss and makes a very low line/space ratio possible. In particular, this may be highly advantageous for high frequency applications.

Furthermore, it should be said that detail 136 does not necessarily show the true thickness relations between the first electrically conductive layer 112a and the second electrically conductive layer 112b. For example, the first electrically conductive layer 112a (which may be formed by electroless deposition) may have a thickness in a range from 50 nm to 1 μm, in particular in a range from 100 nm to 500 nm, for example 200 nm. The second electrically conductive layer 112b (which may be formed by galvanic plating) may have a larger thickness than the first electrically conductive layer 112a. For instance, the thickness of the second electrically conductive layer 112b may be in a range from 1 μm to 100 μm, in particular in a range from 2 μm to 5 μm, for example 3 μm.

Although not shown, any desired build-up of one or more additional electrically conductive layer structures 104 and/or electrically insulating layer structures 106 may be formed in the following. Such additional layer structures 104, 106 may be attached to the upper side of FIG. 3 and/or to the lower side of FIG. 3 and may be connected by lamination, i.e. the application of heat and/or pressure. It is also possible to repeat once or multiple times the formation of electrically conductive material 112 in the way shown and described referring to FIG. 1 to FIG. 3 on stack 102. In particular, this may involve the execution of the described concept of sandwiching a thin film-type adaptive sheet 114 between halogen-including stack portions and each additional formed photosensitive adhesion promoter 108. Furthermore, this may involve the execution of the described concept of spatially selective photoactivating only a sub-portion 110 of each photosensitive adhesion promoter 108 by a spatially dependent heat impact (preferably defined by an electromagnetic radiation beam treating only sub-portion 110, but not non-photoactivated sub-portions 134). This enables the formation of traces with precise rectangular cross-section and with low line/space ratio without the high effort of depositing and photolithographically patterning photoresist or dry film, as well as etching and stripping the latter.

As a result of the described manufacturing process, the illustrated PCB-type component carrier 100 according to an exemplary embodiment of the present disclosure is obtained. Said component carrier 100 comprises the laminated layer stack 102 composed of electrically conductive layer structure(s) 104 and electrically insulating layer structure(s) 106. Adaptive sheets 114 are formed on and adhere with the stack 102 at both opposing main surfaces thereof. A respective layer of photosensitive adhesion promoter 108 is formed on and adheres with a respective one of the adaptive sheets 114. Each photosensitive adhesion promoter 108 may be a full photosensitive adhesion promoter layer arranged parallel to the layer structures 104, 106 of the stack 102. In each photosensitive adhesion promoter 108, only a sub-portion 110 of the photosensitive adhesion promoter 108 is photoactivated to thereby activate the adhesion promoting function, whereas adjacent non-photoactivated sub-portions 134 are not photoactivated and therefore do not offer an adhesion promoting function. Thus, sub-portion 110 of the photosensitive adhesion promoter 108 has adhesion promoting properties whereas the remaining other sub-portions 134 of the photosensitive adhesion promoter 108 have non-adhesion promoting properties. By photoactivation using a UV beam (preferably a spatially properly confined laser beam), polymer dendrites 132 with increased connection surface may be formed in the photoactivated sub-portion 110 of the photosensitive adhesion promoter 108 only. Consequently, the photosensitive adhesion promoter 108 has a higher roughness in a photoactivated sub-portion 110 compared to a remaining other sub-portion 134 thereof. In a cross-sectional view, rectangular structures of electrically conductive material 112 are formed selectively on said sub-portion 110 of each photosensitive adhesion promoter 108, but not on the respective non-photoactivated sub-portions 134. Hence, the non-photoactivated other portions 134 of the photosensitive adhesion promoter 108 remain uncovered by the electrically conductive material 112. Advantageously, the electrically conductive material 112 has a precisely defined rectangular shape in a cross-sectional view and is free of an undercut. For instance, the electrically conductive material 112 on the photosensitive adhesion promoter 108 may be configured as trace, pad, or pillar, or can be used for vias and/or plated through holes.

Highly advantageously, the adaptive sheet 114 may be made of a non-halogenated resin, for instance a non-halogenated prepreg, in order to keep the adhesion promoting function of the photosensitive adhesion promoter 108 intact. Moreover, the adaptive sheet 114 may be free of filler particles or may comprise filler particles. Advantageously, the adaptive sheet 114 may have a small thickness d of not more than 5 μm, so that it does not contribute significantly to the thickness of the component carrier 100 which can thereby be manufactured in a compact way. In particular, the thickness D of each of the electrically insulating layer structures 106 may be significantly larger than the thickness d of the adaptive sheet 114. In view of the presence of the adaptive sheets 114, there is substantially no limitation on the material of the electrically insulating layer structure(s) 106 which increases the freedom of design of a component carrier designer. For instance, it is possible to use cheap electrically insulating layer structures 106 which comprise a halogenated resin without compromising on the intra-layer adhesion of the component carrier 100. Hence, component carrier 100 is not prone to delamination even if cheap electrically insulating layer structures 106 with halogenated resin are used.

As a result of the described manufacturing method, the electrically conductive material 112 may define a wiring structure having a line/space ratio of not more than 5 μm/5 μm, or even of not more than 2 μm/2 μm. In this context, the term line/space ratio may denote a ratio between a line width, L, of a trace-type rectangular-shaped electrically conductive material 112 (as shown in FIG. 3) and a distance between neighbored sidewalls 140 of two neighbored trace-type rectangular-shaped electrically conductive materials 112 (only one being shown in FIG. 3 on each main surface of the component carrier 100).

In the component carrier 100 according to FIG. 3, the copper structures in form of the electrically conductive material 112 may be built only on the activated areas or sub-portions 110 of the adhesion promoter 108. Advantageously, the illustrated semi-additive processing (SAP) may be carried out on all base materials of stack 102 including prepregs. A foot free geometry of the electrically conductive material 112 is obtained, i.e. without undercuts. No flash etching and no dry film is needed for manufacturing patterned electrically conductive material 112. Preferably, the adhesion promoter 108 is only applied on halogen free material to ensure proper adhesion and a delamination-free property of the component carrier 100.

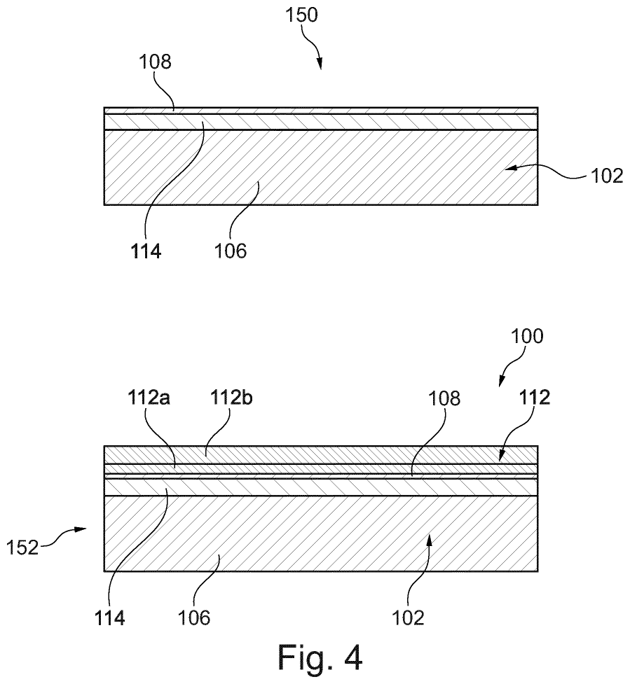

FIG. 4 illustrates cross-sectional views of a component carrier 100 according to an exemplary embodiment of the present disclosure. A first image 150 in FIG. 4 shows a layer sequence before formation of electrically conductive material 112. A second image 152 in FIG. 4 shows the layer sequence after formation of the electrically conductive material 112. The embodiment of FIG. 4 differs from the embodiment of FIG. 1 to FIG. 3 in that, according to FIG. 4, only one side (rather than both sides) of the component carrier 100 is treated with an adhesive sheet 114 and a photosensitive adhesion promoter 108. Moreover, the entire surface of the photosensitive adhesion promoter 108 is covered with electrically conductive material 112 according to FIG. 4.

Preferably, the illustrated adaptive sheet 114 can be made from the same base material resin system as the underlying electrically insulating layer structure 106 of stack 102, but without halogens. Moreover, the adaptive sheet 114 can be a prepreg using halogen free materials with high electrical performance and low thickness to avoid any impact on the impedance and on a signal and may be provided to fit to the used adhesion promoter 108. For example, the adaptive sheet 114 can be laminated or pressed on the base material, i.e. the underlying stack 102. If the thickness is enough to prevent halogens to diffusion to the surface, then the adaptive sheet 114 and the base material of the stack 102 can be pressed at the same time.

It should be noted that the term “comprising” does not exclude other elements or steps and the “a” or “an” does not exclude a plurality. Also elements described in association with different embodiments may be combined.

Implementation of the present disclosure is not limited to the preferred embodiments shown in the figures and described above. Instead, a multiplicity of variants are possible which use the solutions shown and the principle according to the present disclosure even in the case of fundamentally different embodiments.

1. A component carrier, wherein the component carrier comprises:
a stack comprising at least one electrically conductive layer structure and/or at least one electrically insulating layer structure;
a photosensitive adhesion promoter on or above the stack, wherein only a sub-portion of the photosensitive adhesion promoter is photoactivated; and
electrically conductive material selectively on said sub-portion of the photosensitive adhesion promoter.

2. A component carrier, wherein the component carrier comprises:
a stack comprising at least one electrically conductive layer structure and/or at least one electrically insulating layer structure;
an adaptive sheet formed on and adhering with the stack;
a photosensitive adhesion promoter formed on and adhering with the adaptive sheet; and
electrically conductive material formed on and adhering with at least part of the photosensitive adhesion promoter.

3. The component carrier according to claim 2, wherein the electrically conductive material has a rectangular shape in a cross-sectional view.

4. The component carrier according to claim 2, wherein the electrically conductive material is free of an undercut.

5. The component carrier according to claim 2,
comprising at least one of the following features:
wherein the adaptive sheet is made of a non-halogenated material;
wherein the adaptive sheet is configured for functionally decoupling the photosensitive adhesion promoter with regard to a closest one of the at least one electrically insulating layer structure of the stack, wherein the photosensitive adhesion promoter would be partially or entirely functionally inactivated by the closest one of the at least one electrically insulating layer structure without the adaptive sheet;
wherein the adaptive sheet is in direct physical contact with one of the at least one electrically insulating layer structure of the stack;
wherein the adaptive sheet has a thickness of not more than 5 μm.

6. The component carrier according to claim 2, comprising at least one of the following features:
wherein the at least one electrically insulating layer structure comprises a halogenated material;
wherein the at least one electrically insulating layer structure comprises a non-halogenated material;
wherein the electrically conductive material defines a wiring structure having a line/space ratio of not more than 5 μm/5 μm.

7.-8. (canceled)

9. The component carrier according to claim 2, comprising at least one of the following features:
wherein the photosensitive adhesion promoter comprises dendrites in its photoactivated state;
wherein the photoactivated sub-portion of the photosensitive adhesion promoter comprises dendrites;
wherein a non-photoactivated portion of the photosensitive adhesion promoter comprises a grafting chemistry configured for forming dendrites in its photoactivated state.

10. The component carrier according to claim 2, comprising at least one of the following features:
wherein the electrically conductive material on the photosensitive adhesion promoter forms one of the group consisting of at least one pad, at least one wiring structure, at least one pillar, and at least one seed layer in a hole in the stack;
wherein the photosensitive adhesion promoter has a higher roughness in a photoactivated sub-portion compared to a remaining other sub-portion of the photosensitive adhesion promoter;
wherein the photosensitive adhesion promoter and the at least one electrically insulating layer structure comprise different resin materials.

11.-12. (canceled)

13. The component carrier according to claim 2, wherein a thickness of the at least one electrically insulating layer structure is larger than a thickness of the adaptive sheet.

14. The component carrier according to claim 2, wherein a photoactivated sub-portion of the photosensitive adhesion promoter has adhesion promoting properties whereas another non-photoactivated sub-portion of the photosensitive adhesion promoter has no adhesion promoting properties.

15. The component carrier according to claim 2, wherein the photosensitive adhesion promoter is a photosensitive adhesion promoter layer arranged parallel to the layer structures of the stack.

16. The component carrier according to claim 2, wherein a non-photoactivated portion of the photosensitive adhesion promoter is not covered by electrically conductive material.

17. The component carrier according to claim 2, wherein the electrically conductive material comprises a first electrically conductive layer on the photosensitive adhesion promoter and comprises a second electrically conductive layer on the first electrically conductive layer.

18. (canceled)

19. A method of manufacturing a component carrier, wherein the method comprises:
providing a stack comprising at least one electrically conductive layer structure and/or at least one electrically insulating layer structure;
forming an adaptive sheet on and adhering with the stack;
forming a photosensitive adhesion promoter on and adhering with the adaptive sheet; and
forming electrically conductive material on and adhering with at least part of the photosensitive adhesion promoter.

20. The method according to claim 19, comprising at least one of the following features:
wherein the method comprises forming at least part of the electrically conductive material by electroless deposition;
wherein the method comprises forming the electrically conductive without etching;
wherein the method comprises activating the photosensitive adhesion promoter by supplying heat.

21.-23. (canceled)

24. The method according to claim 19, wherein the method comprises selectively treating a sub-portion of the photosensitive adhesion promoter with heat, to thereby define a partial area on which the electrically conductive material is selectively depositable.

25. The method according to claim 19, wherein the method comprises forming the electrically conductive material as a first electrically conductive layer and a separate second electrically conductive layer on the first electrically conductive layer.

26. The method according to claim 25, wherein the method comprises forming the first electrically conductive layer by electroless deposition, and the second electrically conductive layer by a galvanic process.

27. The method according to claim 19, wherein the method comprises providing the photosensitive adhesion promoter with a grafting chemistry configured to alter a surface of resin for promoting a subsequent formation of electrically conductive material when photoactivated.

28. The component carrier according to claim 2, wherein the adaptive sheet is configured for functionally decoupling the photosensitive adhesion promoter with regard to the stack, wherein the photosensitive adhesion promoter would be partially or entirely functionally inactivated by the stack without the adaptive sheet.
